(19) United States
(12) Patent Application Publication
(10) Pub. No.: US 2018/0137927 A1
(43) Pub. Date: May 17, 2018

(54) Three-Dimensional Vertical One-Time-Programmable Memory Comprising No Separate Diode Layer

(71) Applicant: Guobiao ZHANG, Corvallis, OR (US)

(72) Inventor: Guobiao ZHANG, Corvallis, OR (US)

(73) Assignee: ChengDu HaiCun IP Technology LLC, ChengDu (CN)

(21) Appl. No.: 15/870,855

(22) Filed: Jan. 13, 2018

Related U.S. Application Data
(63) Continuation-in-part of application No. 15/488,489, filed on Apr. 16, 2017.

(30) Foreign Application Priority Data
Apr. 16, 2016 (CN) 201610234999.5
Jan. 10, 2018 (CN) 201810022003.3
Jan. 10, 2018 (CN) 201810024499.8

(51) Int. Cl. G11C 17/16; H01L 23/525; H01L 27/112

(52) U.S. Cl. CPC G11C 17/16; H01L 27/1128; H01L 23/5252

(57) ABSTRACT

The present invention discloses a three-dimensional vertical read-only memory (3D-OTP_{V}) comprising no separate diode layer. It comprises a plurality of vertical address line, a plurality of memory holes through said vertical address line, a plurality of antifuse layers and vertical address lines in said memory holes. The memory holes comprise no separate diode layer. The horizontal and vertical address lines comprise different metallic materials.

### CROSS-REFERENCE TO RELATED APPLICATIONS

This application is a continuation-in-part of “Three-Dimensional Vertical One-Time-Programmable Memory”, application Ser. No. 15/488,489, filed on Apr. 16, 2017, which claims priority from Chinese Patent Application 201610234999.5, filed on Apr. 16, 2016, in the State Intellectual Property Office of the People's Republic of China (CN), the disclosure of which is incorporated herein by reference in its entirety.

This application also claims priority from Chinese Patent Application 201810022003.3, filed on Jan. 10, 2018; Chinese Patent Application 201810024499.8, filed on Jan. 10, 2018; in the State Intellectual Property Office of the People's Republic of China (CN), the disclosure of which are incorporated herein by references in their entireties.

### BACKGROUND

### 1. Technical Field of the Invention

The present invention relates to the field of integrated circuit, and more particularly to one-time-programmable memory (OTP).

### 2. Prior Art

Three-dimensional one-time-programmable memory (3D-OTP) is a monolithic semiconductor memory. It comprises a plurality of vertically stacked OTP cells. In a conventional OTP, the OTP cells are formed on a two-dimensional (2-D) plane (i.e. on a semiconductor substrate). In contrast, the OTP cells of the 3D-OTP are formed in a three-dimensional (3-D) space. The 3D-OPT has a large storage density and a low storage cost. Because the 3D-OTP has a long data retention, it is suitable for long-term data storage.

U.S. patent application Ser. No. 15/360,895 filed by Hsu on Nov. 23, 2016 discloses a 3-D vertical memory. It comprises a plurality of horizontal address lines vertically stacked above each other, a plurality of memory holes penetrating the horizontal address lines, a programmable layer (e.g. an antifuse layer) and a selector layer covering the sidewall of each memory hole, and a plurality of vertical address lines formed in the memory holes. It should be noted that the selector (or, selector layer) is also referred to as diode (or, diode layer), steering element, quasi-conduction layer, or other names in other patents and patent applications. All of them refer to a broad class of diode-like devices whose resistance at the read voltage (i.e. the read resistance) is substantially lower than when the applied voltage has a magnitude smaller than or a polarity opposite to that of the read voltage. Throughout this specification, the term “diode” is used for this class of devices.

The 3-D vertical memory of Hsu uses a cross-point array. In order to minimize cross-talk between memory cells, the memory cell of Hsu comprises a separate diode layer (i.e. selector). A good-quality diode layer is generally thick. For example, a P-N thin-film diode with a good rectifying ratio is at least 100 nm thick. When a diode layer with such a thickness is formed in the memory hole, the diameter of the memory hole becomes large (>200 nm). This leads to a lower storage density.

### Objects and Advantages

It is a principle object of the present invention to provide a 3D-OTP with a large storage capacity.

It is a further object of the present invention to simplify the manufacturing process inside the memory holes.

It is a further object of the present invention to minimize the size of the memory holes.

It is a further object of the present invention to provide a properly working 3D-OTP even with leaky OTP cells.

In accordance with these and other objects of the present invention, the present invention discloses a three-dimensional vertical one-time-programmable memory (3D-OTP_{V}) comprising no separate diode layer.

### SUMMARY OF THE INVENTION

The present invention discloses three-dimensional vertical one-time-programmable memory (3D-OTP_{V}) comprising no separate diode layer. It comprises a plurality of vertical OTP strings formed side-by-side on the substrate circuit. Each OTP string is vertical to the substrate and comprises a plurality of vertically stacked OTP cells. To be more specific, the 3D-OTP_{V} comprises a plurality of vertically stacked horizontal address lines (word lines). After the memory holes penetrating these horizontal address lines are formed, the sidewall of each memory hole is covered with an antifuse layer before the memory hole is filled with at least a conductive material, which comprises a metallic material or a doped semiconductor material. The conductive material in each memory hole forms a vertical address line (bit line). The OTP cells are formed at the intersections of the word lines and the bit lines.

To minimize the size of the memory holes, the OTP cell of the present invention comprises no diode layer. Without diode layer, fewer layers (two instead of three) are formed inside the memory holes. As a result, the manufacturing process inside the memory holes becomes simpler. In addition, smaller memory holes will improve the storage density of the 3D-OTP_{V}.

In the OTP cell of the present invention, a diode is formed naturally between the horizontal and vertical address lines. This naturally formed diode, referred to a built-in diode, generally has a poor quality and is leaky. To address this issue, the present invention discloses a full-read mode. For the full-read mode, all OTP cells on a selected word line are read out during a read cycle. The read cycle includes two read phases: a pre-charge phase and a read-out phase. During the pre-charge phase, all address lines (including all word and all bit lines) in an OTP array are charged to a pre-determined voltage. During the read-out phase, after its voltage is raised to the read voltage V_{R}, a selected word line starts to charge all bit lines through the associated OTP cells. By measuring the voltage change on the bit lines, the states of the associated OTP cells can be determined.

Accordingly, the present invention discloses a three-dimensional vertical read-only memory (3D-OTP_{V}), comprising: a semiconductor substrate comprising a substrate circuit; a plurality of vertically stacked horizontal address lines above said semiconductor circuit, said horizontal address lines comprising a first metallic material; at least a memory hole through said plurality of horizontal address lines; an antifuse layer formed on the sidewall of said memory hole, wherein said antifuse layer is irreversibly switched from a high-resistance state to a low-resistance state during programming; a vertical address line formed by filling at least a conductive material in said memory hole, said vertical address lines comprising a second metallic material; a plurality of OTP cells formed at the intersections of said horizontal address lines and said vertical address line; said first and second metallic materials are different metallic materials.

### BRIEF DESCRIPTION OF THE DRAWINGS

FIG. 1A is a z-x cross-sectional view of a first preferred 3D-OTP_{V}; FIG. 1B is its x-y cross-sectional view along the cutline AA′; FIG. 1C is a z-x cross-sectional view of a preferred OTP cell;

FIGS. 2A-2C are cross-sectional views of the first preferred 3D-OTP_{V} at three manufacturing steps;

FIG. 3A is a symbol of the OTP cell; FIG. 3B is a circuit block diagram of a first preferred read-out circuit for an OTP array; FIG. 3C is its signal timing diagram; FIG. 3D shows the current-voltage (I-V) characteristic of a preferred diode layer;

FIG. 4A is a z-x cross-sectional view of a second preferred 3D-OTP_{V}; FIG. 4B is its x-y cross-sectional view along the cutline CC′; FIG. 4C is a circuit block diagram of a second preferred read-out circuit for an OTP array;

FIG. 5 is a cross-sectional view of a multi-bit-per-cell 3D-OTP_{V}.

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments. The symbol “/” means a relationship of “and” or “or”.

Throughout the present invention, the phrase “on the substrate” means the active elements of a circuit are formed on the surface of the substrate, although the interconnects between these active elements are formed above the substrate and do not touch the substrate; the phrase “above the substrate” means the active elements are formed above the substrate and do not touch the substrate.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

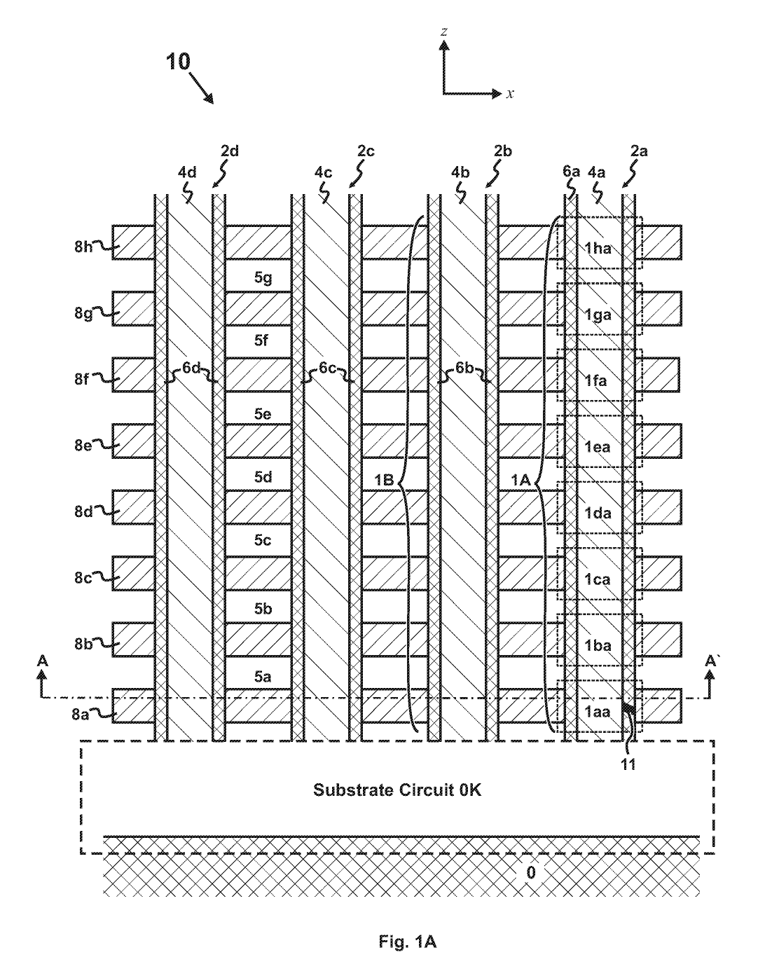

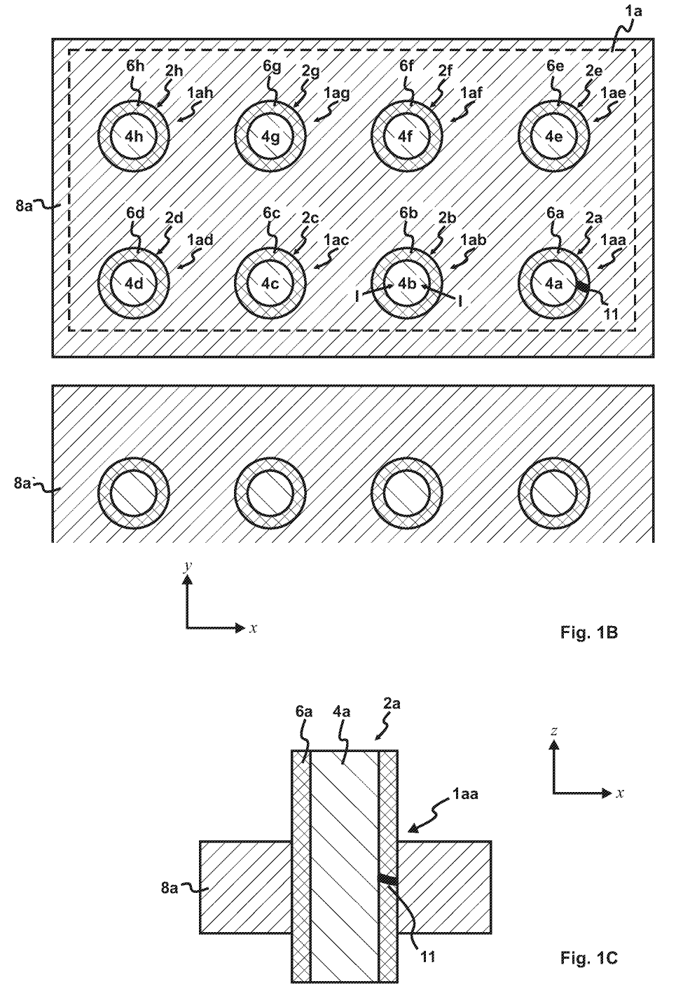

Referring now to FIG. 1A-1C, a first preferred three-dimensional vertical one-time-programmable memory (3D-OTP_{V}) comprising no separate diode layer is disclosed. It comprises a plurality of vertical OTP strings 1A, 1B . . . (referred to as OTP strings) formed side-by-side on the substrate circuit 0K. Each OTP string (e.g. 1A) is vertical to the substrate 0 and comprises a plurality of vertically stacked OTP cells 1aa-1ha.

The preferred embodiment shown in this figure is an OTP array 10, which is a collection of all OT cells sharing at least an address line. It comprises a plurality of vertically stacked horizontal address lines (word lines) 8a-8h. After the memory holes 2a-2d penetrating these horizontal address lines 8a-8h are formed, the sidewalls of the memory holes 2a-2d are covered with an antifuse layer 6a-6d before the memory holes 2a-2d are filled with at least a conductive material, which comprise a metallic material or a doped semiconductor material. The conductive material in the memory holes 2a-2d form vertical address lines (bit lines) 4a-4d.

The OTP cells 1aa-1ha on the OTP string 1A are formed at the intersections of the word lines 8a-8h and the bit line 4a. In the OTP cell 1aa, the antifuse layer 6a is a thin layer of insulating dielectric. During programming, a conductive filament 11, which has a low resistance, is irreversibly formed therein. As an example, the antifuse layer 6a comprises silicon oxide or silicon nitride. The thickness of the antifuse layer 6a is small, typically in the range of several nanometers to tens of nanometers. For reason of simplicity, except for the OTP cell 1aa, the conductive filaments in other OTP cells are not drawn.

FIG. 1B is its x-y cross-sectional view along the cutline AA′. Each of the horizontal address lines (word lines) 8a, 8a′ is a conductive plate. The horizontal address line 8a is coupled with eight vertical address lines (bit lines) 4a-4h. Eight OTP cells 1aa-1ah are formed at the intersections of the horizontal address 8a and the vertical address lines 4a-4h. All OTP cells 1aa-1ah coupled with a single horizontal address line 8a form an OTP-cell set 1a. Because the horizontal address line 8a is wide, it can be formed by a low-resolution photolithography (e.g. with feature size >60 nm).

To minimize the size of the memory holes, the OTP cell of the present invention does not comprise a separate diode layer. As shown in FIG. 1C, the OTP cell 1aa comprises a separate antifuse layer 6a, but no separate diode layer. Because no diode layer is formed on the sidewall of the memory hole 2a, the manufacturing process inside the memory hole 2a becomes simpler. In addition, smaller memory hole 2a will improve the storage density of 3D-OTP_{V}.

In the present invention, diode is formed naturally between the horizontal address line 8a and the vertical address line 4a. This diode is referred to as built-in diode. In a first preferred embodiment, the horizontal address line 8a comprises a P-type semiconductor material, while the vertical address line 4a comprises an N-type semiconductor material. The built-in diode is a semiconductor diode. In a second preferred embodiment, the horizontal address line 8a comprises a metallic material, while the vertical address line 4a comprises a semiconductor material. The built-in diode is a Schottky diode. In a third preferred embodiment, the horizontal address line 8a comprises a semiconductor material, while the vertical address line 4a comprises a metallic material. The built-in diode is a Schottky diode.

Alternatively, in a fourth preferred embodiment, the horizontal address line 8a comprises a first metallic material, while the vertical address line 4a comprises a second metallic material. The first and second metallic materials are different metallic materials. For example, the first and second metallic materials have different work functions. During programming, when the antifuse layer 6a breaks down at location 11, the metallic material from one of the address lines (e.g. the second metallic material from the vertical address line 4a) reacts with the antifuse material (e.g. silicon oxide) to form a metallic compound (e.g. metal oxide of the second metallic material). As a result, a diode comprising the first metallic material, the metallic compound, and the second metallic material will be formed between the horizontal address line 8a and the vertical address line 4a.

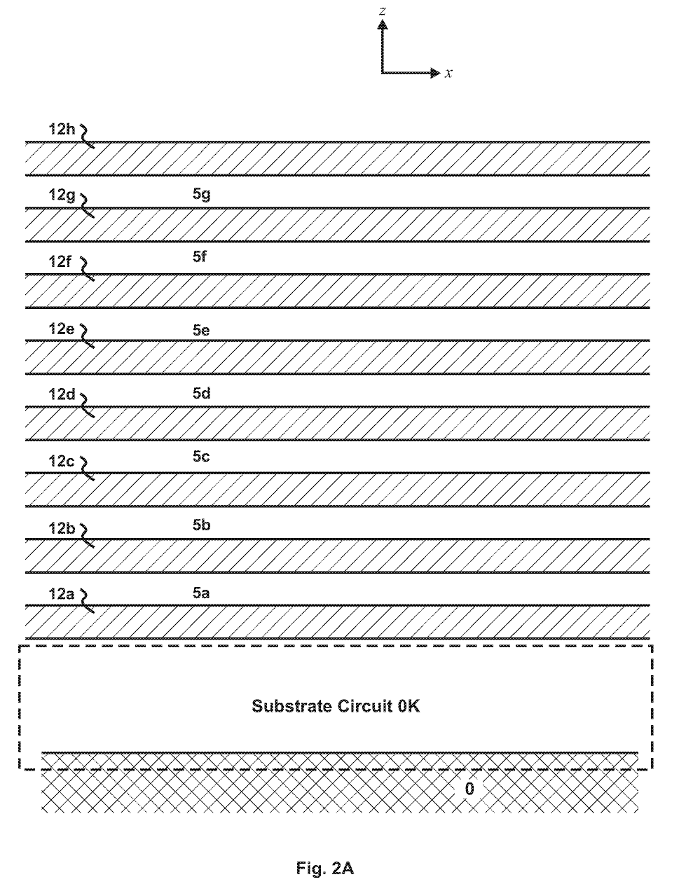

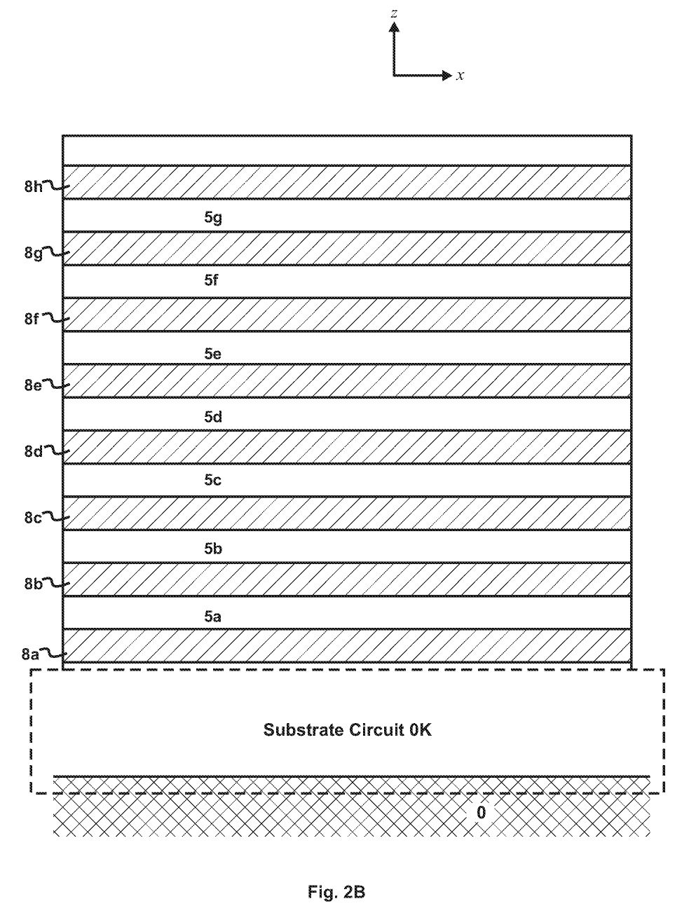

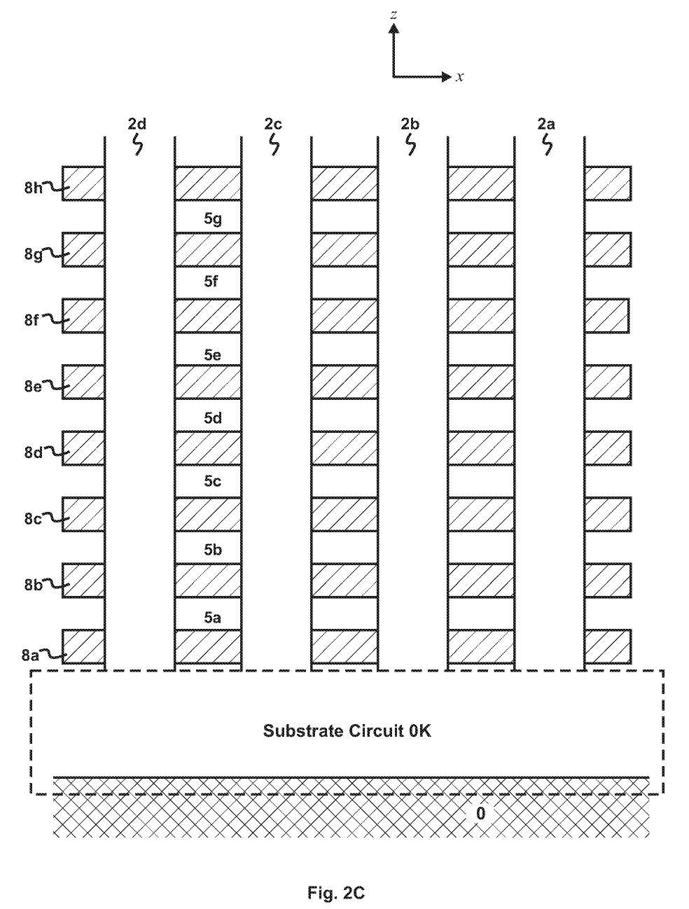

Referring now to FIGS. 2A-2C, three manufacturing steps for the preferred 3D-OTP_{V} are shown. First of all, vertically stacked horizontal address-line layers 12a-12h are formed in continuously forming steps (FIG. 2A). To be more specific, after the substrate circuit 0K (including transistors and the associated interconnects) are planarized, a first horizontal address-line layer 12a is formed. The first horizontal address-line layer 12a is just a plain layer of conductive materials and contains no patterns. Then a first insulating layer 5a is formed on the first horizontal address-line layer 12a. Similarly, the first insulating layer 5a contains no patterns. Repeating the above process until alternate layers of the horizontal address-line layers and the insulating layers (a total of M layers) are formed. “Continuously forming steps” means that these forming steps (for the horizontal address-line layer and the insulating layer) are carried out continuously without any in-between pattern-transfer steps (including photolithography). Without any in-between pattern-transfer steps, excellent planarization can be achieve. As a result, the 3D-OTP_{V} comprising tens to hundreds of horizontal address-line layers can be formed. This is significantly more than the 3D-OPT_{H}.

A first etching step is performed through all horizontal address-line layers 12a-12h to form a stack of horizontal address lines 8a-8h in (FIG. 2B). This is followed by a second etching step to form memory holes 2a-2d through all horizontal address lines 8a-8h (FIG. 2C). The sidewall of the memory holes 2a-2d is covered by an antifuse layers 6a-6d before the memory holes 2a-2d are filled with at least a conductive material to form the vertical address lines 4a-4d (FIG. 1A).

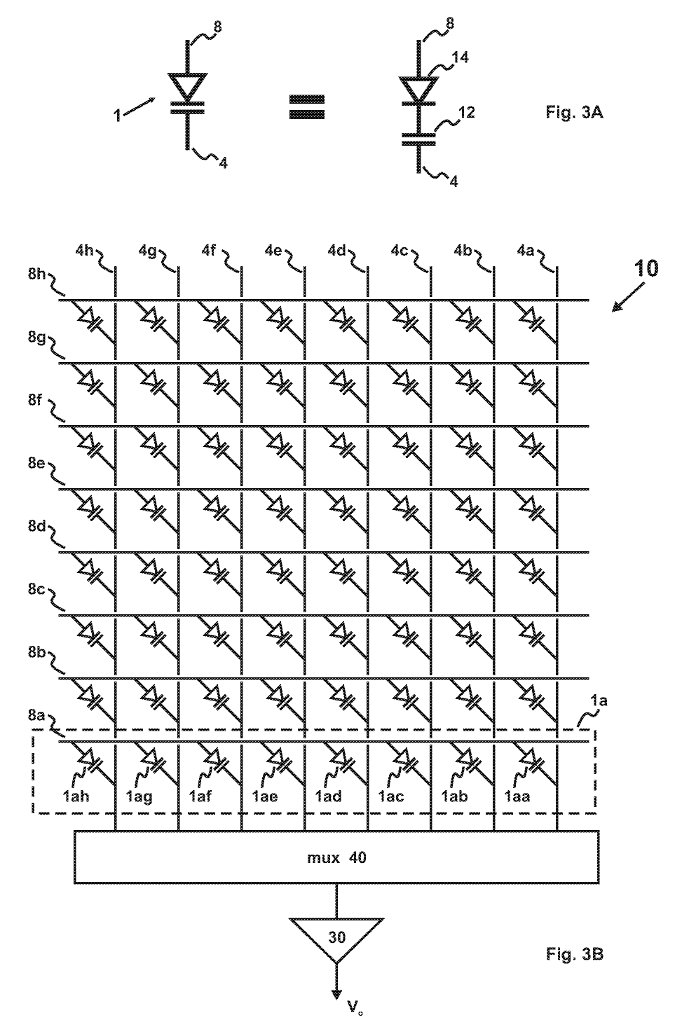

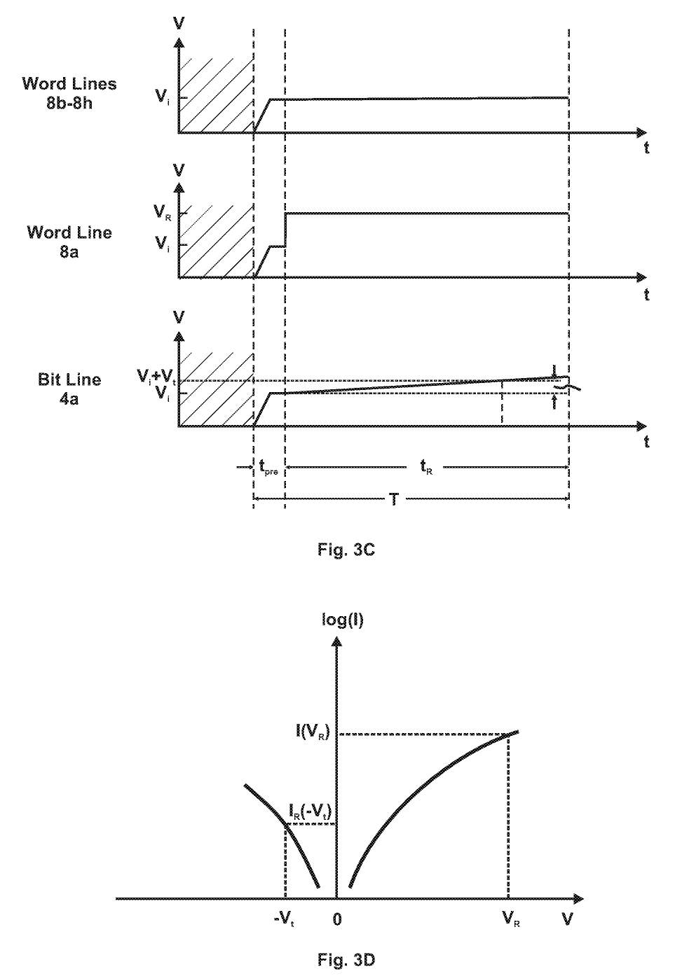

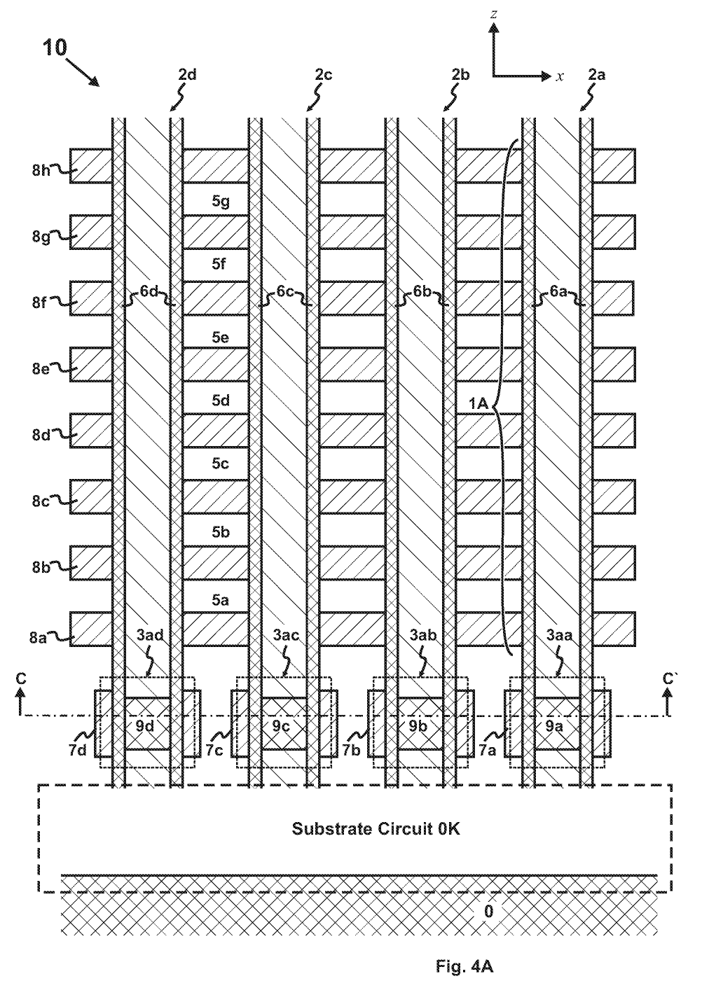

FIG. 3A is a symbol of the OTP cell 1. The OTP cell 1, located between a word line 8 and a bit line 4, comprises an antifuse 12 and a diode 14. The resistance of the antifuse 12 is irreversibly switched from high to low during programming. The resistance of the diode 14 at the read voltage is substantially lower than when the applied voltage has a magnitude smaller than or polarity opposite to that of the read voltage.

The diode 14 is formed naturally between the word line 8 and the bit lines 4. This naturally formed diode 14, referred to a built-in diode, generally has a poor quality and is leaky. To address this issue, the present invention discloses a full-read mode. For the full-read mode, all OTP cells on a selected word line are read out during a read cycle.

FIG. 3B discloses a first preferred read-out circuit for an OTP array 10. It runs in the full-read mode. In this preferred embodiment, the horizontal address lines 8a-8h are word lines, while the vertical address lines 4a-4h are bit lines. An OTP array 10 comprises the word lines 8a-8h, the bit lines 4a-4h, and the OTP cells 1aa-1ad . . . located at their intersections. Its peripheral circuits (located on the substrate 0 and is not part of the OTP array 10) comprise a multiplexor 40 and an amplifier 30. In this preferred embodiment, the multiplexor 40 is a 4-to-1 multiplexor.

FIG. 3C is its signal timing diagram. A read cycle T includes two read phases: a pre-charge phase tₚᵣₑ and a read-out phase t_{R}. During the pre-charge phase tₚᵣₑ, all address lines 8a-8h, 4a-4h in the OTP array 10 are charged to a pre-determined voltage (e.g. an input bias voltage Vᵢ of the amplifier 30). During the read-out phase t_{R}, all bit lines 4a-4h are floating. The voltage on a selected word line (e.g. 8a) is raised to the read voltage V_{R}, while voltage on other word lines 8b-8h remains at the input bias voltage Vᵢ. After this, the selected word line 8a starts to charge all bit lines 4a-4h through the OTP cells 1aa . . . and the voltages on the bit lines 4a-4h begin to rise. The multiplexor 40 sends the voltage on each bit line (e.g. 4a) to the amplifier 30. When this voltage exceeds the threshold voltage V_{T} of the amplifier 30, the output V_{O} is toggled. At the end of the read cycle T, the states of all OTP cells 1aa-1ah in the OTP-cell set 1a are determined.

FIG. 3D shows the current-voltage (I-V) characteristic of a preferred diode layer. Because the V_{T} of the amplifier 30 is relatively small (˜0.1V or smaller), the voltage changes delta(V) on the bit lines 4a-4h during the above measurement are small, i.e. delta(V)˜V_{T}. The reverse voltage on the unselected OTP cells (e.g. 1 ca) is ˜V_{T}. As long as the I-V characteristic of the diode satisfies I(V_{R})>>n*I(−V_{T}), the 3D-OTP_{V} would work properly. Here, n is the number of OTP cells on a bit line (e.g. 4a). It should be noted that, because the value of V_{R} (several volts) is far larger than that of the −V_{T} (˜0.1V), even if the OTP cells are leaky, the above condition can be easily met.

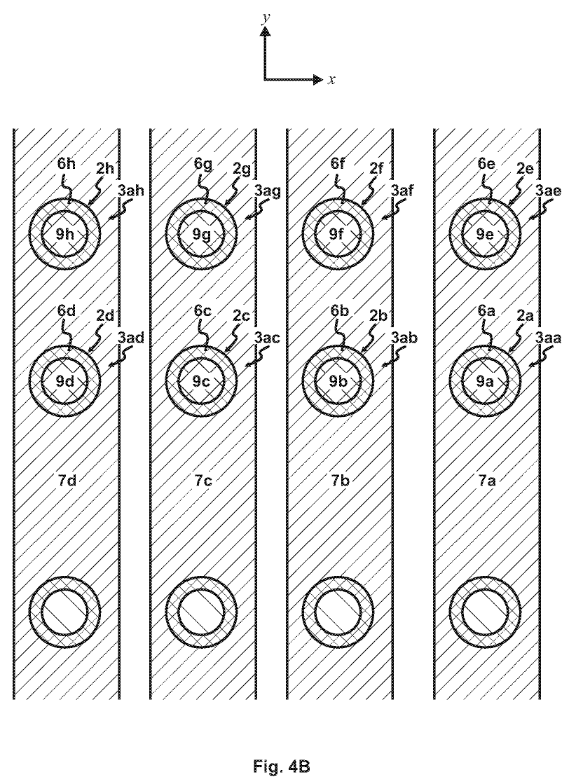

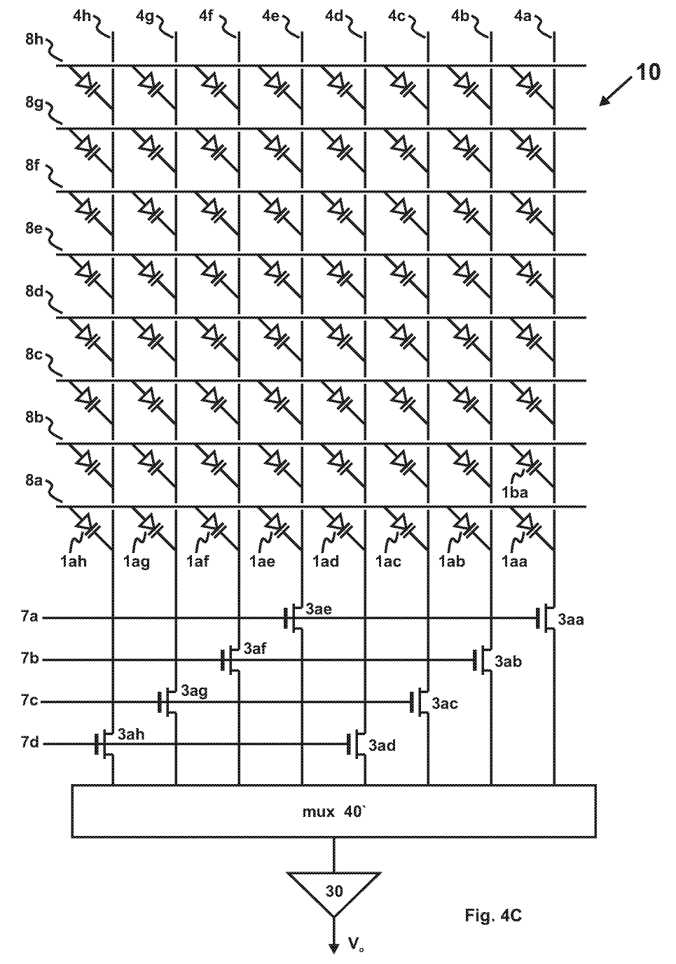

To facilitate address decoding, vertical transistors are formed on the sidewalls of the memory holes. FIGS. 4A-4C disclose a second preferred 3D-OTP_{V} 10 comprising vertical transistors 3aa-3ad. The vertical transistor 3aa is a pass transistor comprising a gate 7a, a gate dielectric 6a and a channel 9a (FIG. 4A). The channel 9a is formed in the semiconductor material filled in the memory hole 2a. Its doping could be same as, lighter than, or opposite to that of the vertical address line 4a. The gate 7a surrounds the memory holes 2a, 2e and controls the pass transistors 3aa, 3ae (FIG. 4B); the gate 7b surrounds the memory holes 2b, 2f and controls the pass transistors 3ab, 3af; the gate 7c surrounds the memory holes 2c, 2g and controls the pass transistors 3ac, 3ag; the gate 7d surrounds the memory holes 2e, 2h and controls the pass transistors 3ae, 3ah. The pass transistors 3aa-3ah form at least a decoding stage (FIG. 4C). In one preferred embodiment, when the voltage on the gate 7a is high while the voltages on the gates 7b-7d are low, only the pass transistors 3aa, 3ae are turn on, with other pass transistors off. The substrate multiplexor 40′ is a 2-to-1 multiplexor which selects a signal from the bit lines 4a, 4e. By forming vertical transistors 3aa-3d in the memory holes 2a-2d, the decoder design could be simplified.

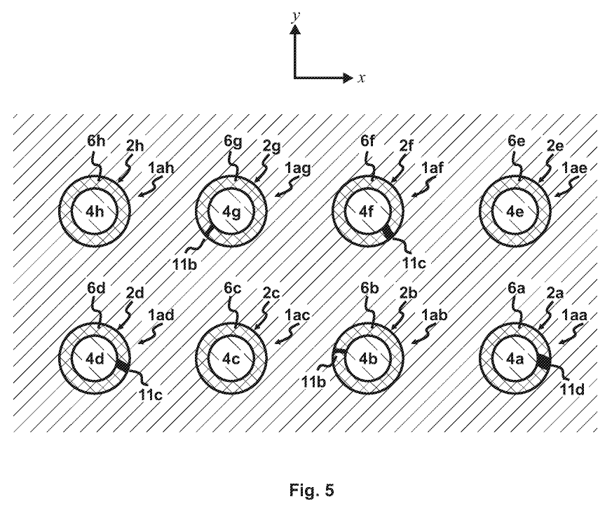

FIG. 5 discloses a multi-bit-per-cell 3D-OTP_{V}. It comprises a plurality of OTP cells 1aa-1ah. In this preferred embodiment, the OTP cells 1aa-1ah have four states: ‘0’, ‘1’, ‘2’, ‘3’. The OTP cells 1aa-1ah in different states are programmed by different programming currents and therefore, have different resistance. The OTP cells 1ac, 1ae, 1ah are in the state ‘0’. Being un-programmed, their antifuse layers 6c, 6e, 6h are intact. Other OTP cells are programmed. Among them, the OTP cells 1ab, 1ag are in the state ‘1’, which have the largest resistance as the conductive filaments 11b are the thinnest; the OTP cell 1aa is in the state ‘3’, which has the smallest resistance as the conductive filament 11d is the thickest; the OTP cells 1ad, 1af are in the state ‘2, which have an intermediate resistance as the size of its conductive filament 11c is between those of 11b and 11d.

While illustrative embodiments have been shown and described, it would be apparent to those skilled in the art that many more modifications than that have been mentioned above are possible without departing from the inventive concepts set forth therein. The invention, therefore, is not to be limited except in the spirit of the appended claims.

What is claimed is:

1. A three-dimensional vertical read-only memory (3D-OTP_{V}), comprising:
a semiconductor substrate comprising a substrate circuit;
a plurality of vertically stacked horizontal address lines above said semiconductor circuit, said horizontal address lines comprising a first metallic material;
at least a memory hole through said plurality of horizontal address lines;
an antifuse layer formed on the sidewall of said memory hole, wherein said antifuse layer is irreversibly switched from a high-resistance state to a low-resistance state during programming;
a vertical address line formed by filling at least a conductive material in said memory hole, said vertical address lines comprising a second metallic material;
a plurality of OTP cells formed at the intersections of said horizontal address lines and said vertical address line;
said first and second metallic materials are different metallic materials.

2. The 3D-OTP_{V} according to claim 1, wherein said first and second metallic materials have different work functions.

3. The 3D-OTP_{V} according to claim 1, wherein said first metallic material, said antifuse layer and said second metallic material form a diode during programming.

4. The 3D-OTP_{V} according to claim 3, wherein the resistance of said diode is substantially lower than when the applied voltage has a magnitude smaller than or a polarity opposite to that of the read voltage.

5. The 3D-OTP_{V} according to claim 4, wherein all OTP cells coupled to a selected horizontal address line are read out in a single read cycle.

6. The 3D-OTP_{V} according to claim 5, wherein the voltage on said selected horizontal address line is V_{R}; and the output toggles when the voltage on a selected vertical address line reaches V_{T}.

7. The 3D-OTP_{V} according to claim 6, wherein the I-V characteristics of said diode satisfies I(V_{R})>>n*I(−V_{T}), wherein n is the number of OTP cells on a horizontal address line.

8. The 3D-OTP_{V} according to claim 1, wherein said OTP cells form an OTP string.

9. The 3D-OTP_{V} according to claim 8, further comprising a vertical transistor coupled to said OTP string.

10. The 3D-OTP_{V} according to claim 9, wherein said vertical transistor is formed in a first portion of said memory hole, and said OTP string is formed in a second portion of said memory hole.

11. The 3D-OTP_{V} according to claim 1, wherein said OTP cells have more than two states, the OTP cells in different states having different resistance value after programming.
